(19) United States
(12) Patent Application Publication
(10) Pub. No.: US 2025/0126761 A1
(43) Pub. Date: Apr. 17, 2025

(54) POWER SUPPLY DEVICE

(71) Applicant: Panasonic Automotive Systems Co., Ltd., Kanagawa (JP)

(72) Inventor: Atsushi YAMASHIMA, Kanagawa (JP)

(21) Appl. No.: 18/884,693

(22) Filed: Sep. 13, 2024

(30) Foreign Application Priority Data
Oct. 13, 2023 (JP) 2023-177671

(51) Int. Cl. H05K 7/20

(52) U.S. Cl. CPC H05K 7/209

(57) ABSTRACT

A power supply device according to the present disclosure includes a case, a plurality of types of heat generating components, and an insulating heat dissipation resin material. The case is a box-shaped member having thermal conductivity and formed in a box shape. The plurality of types of heat generating components are housed in the case. The insulating heat dissipation resin material is filled in the case.

### CROSS-REFERENCE TO RELATED APPLICATIONS

This application is based upon and claims the benefit of priority from Japanese Patent Application No. 2023-177671, filed Oct. 13, 2023, the entire contents of which are incorporated herein by reference.

### FIELD

Embodiments described herein relate generally to a power supply device.

### BACKGROUND

In a power supply device used for an inverter etc. mounted on an electric vehicle etc., a power loss of an electronic component such as a semiconductor mounted on a circuit board increases as an output of the electronic component increases. Because the electronic component is likely to generate heat with an increase in power loss, a configuration for efficiently dissipating heat from the electronic component is known.

For example, JP 2017-108007 A discloses a power supply device that dissipates heat from an electronic component by arranging a box-shaped aluminum block in a heat dissipation housing. Specifically, there is disclosed a configuration in which an electronic component such as a field effect transistor (FET) is arranged in contact with an outer wall of an aluminum block, and an electronic component such as a reactor is arranged in the aluminum block.

However, the configuration disclosed in JP 2017-108007 A requires to fix the electronic component to the outer wall of the aluminum block and to ensure insulation between the electronic component and the periphery, and thus, there is a structural restriction in the vicinity of an integrated power module. Therefore, the configuration has a certain limit from the viewpoint of size reduction of the entire device. That is, in the technology according to the related art, it is difficult to ensure heat dissipation of heat generating components and to achieve size reduction of the entire device.

An object of the present disclosure is to provide a power supply device that can ensure heat dissipation of heat generating components and can achieve size reduction of the entire device.

### SUMMARY

A power supply device according to an embodiment of the present disclosure includes a case having thermal conductivity and formed in a box shape, a plurality of types of heat generating components housed in the case, and an insulating heat dissipation resin material filled in the case.

### BRIEF DESCRIPTION OF THE DRAWINGS

FIG. 1 is a perspective view of an example of a power supply device according to an embodiment;

FIG. 2 is a perspective view of an example of a power conversion device;

FIG. 3 is a perspective view of an example of the power conversion device; and

FIG. 4 is a cross-sectional view of an example of the power conversion device.

### DETAILED DESCRIPTION

Hereinafter, an example of a power supply device of an embodiment will be described with reference to the accompanying drawings.

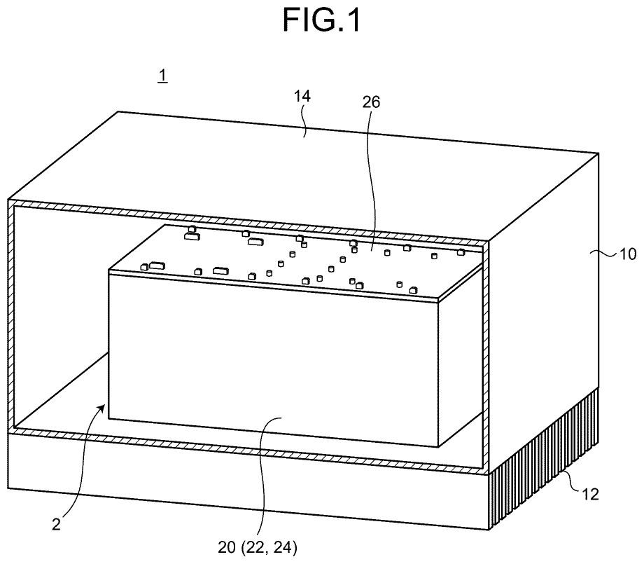

FIG. 1 is a perspective view of an example of a power supply device 1 according to the present embodiment.

The power supply device 1 is a device for supplying power. The power supply device 1 is used for, for example, an in-vehicle charger or an inverter mounted on an electric vehicle or the like.

The power supply device 1 includes a heat dissipation housing 10, a lid 14, and a power conversion device 2.

The heat dissipation housing 10 is formed in a rectangular parallelepiped shape having a bottom wall and four side walls, and is formed in a box shape opened upward. The heat dissipation housing 10 is formed of a member having excellent thermal conductivity, and dissipates heat from the power conversion device 2 housed therein. The heat dissipation housing 10 is formed of a member having excellent thermal conductivity. Examples of the member having excellent thermal conductivity include aluminum, iron, copper, and magnesium.

Fins 12 are formed on an outer surface of the bottom wall of the heat dissipation housing 10. The lid 14 is a member that covers the opening of the heat dissipation housing 10. FIG. 1 illustrates a cross-sectional view of the rectangular parallelepiped heat dissipation housing 10 taken in a direction perpendicular to a bottom surface of the heat dissipation housing 10 on which the fins 12 are provided.

The power conversion device 2 is housed in the heat dissipation housing 10.

The power conversion device 2 includes a case 20 and a circuit board 26. In the case 20, each of heat generating components 22 and an insulating heat dissipation resin material 24 described below is housed and filled (details thereof are described below). A bottom surface of an outer wall of the case 20 is arranged in contact with a bottom surface on an inner wall side of the heat dissipation housing 10.

The circuit board 26 is electrically connected to the heat generating components 22 in the case 20. A predetermined wiring pattern is formed on the circuit board 26, and a predetermined circuit element is mounted thereon. The circuit board 26 is electrically connected to the heat generating components 22 to be used as a printed circuit board configuring a power conversion circuit. Examples of the power conversion circuit include an in-vehicle charger including a power factor correction circuit and a DC/DC converter, or an electric circuit such as an inverter. Specifically, the circuit board 26 of the present embodiment is, for example, a power conversion circuit that supports a high-voltage battery for driving mounted on an electric vehicle or the like and is capable of high output. The circuit board 26 is fixed to bosses (not illustrated) protruding upward from the inner bottom surface of the bottom wall of the heat dissipation housing 10 and four corners of an upper end portion of the case 20 with screws or the like (not illustrated).

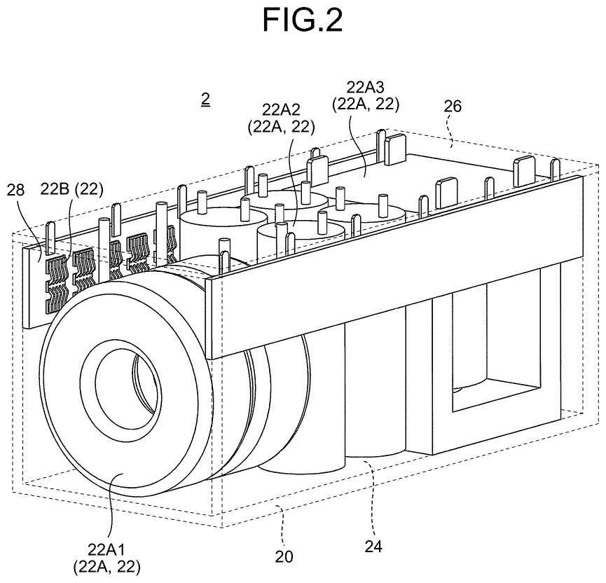

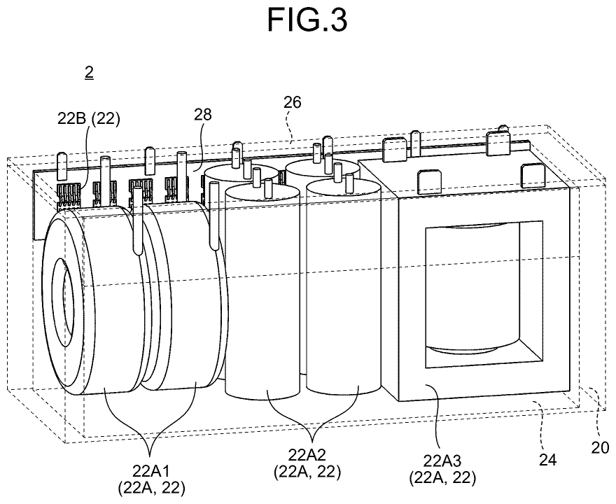

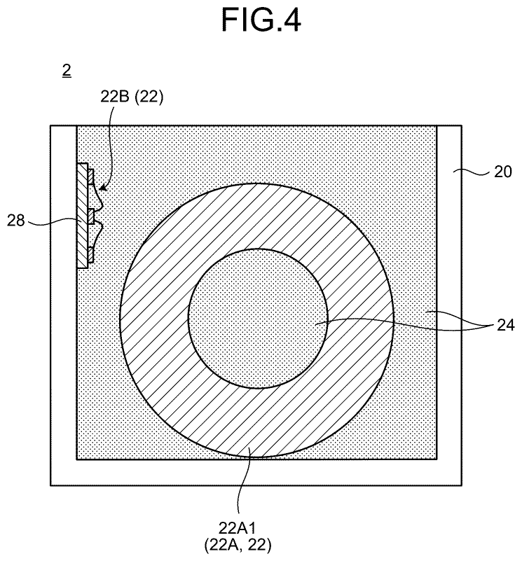

FIG. 2 is a perspective view of the power conversion device 2 included in the power supply device 1. In FIG. 2, a part of the case 20 is schematically transparent. FIG. 3 is a perspective view of the power conversion device 2 illustrated in FIG. 2 when viewed from a direction different from FIG. 2. FIG. 4 is a cross-sectional views obtained by cutting the power conversion device 2 illustrated in FIG. 2 in a certain direction.

The case 20 is a box-shaped member having thermal conductivity and formed in a box shape. For example, the case 20 is formed in a rectangular parallelepiped shape that is opened upward and has a quadrangular bottom wall and four side walls erected in a direction perpendicular to the bottom wall along four sides forming a bottom outer frame of the bottom wall by die casting or the like.

It is sufficient if the case 20 is formed of a material having thermal conductivity. For example, the case 20 is formed of metal such as aluminum, a resin having thermal conductivity, or the like.

The case 20 is arranged in contact with an inner wall of the heat dissipation housing 10. Specifically, the bottom surface of the outer wall of the case 20 is arranged in contact with the bottom surface of the inner wall of the box-shaped heat dissipation housing 10 directly or via a member having thermal conductivity.

The plurality of types of heat generating components 22 and the insulating heat dissipation resin material 24 are housed in the case 20.

It is sufficient if the heat generating components 22 are components that generate heat. The heat generating component 22 is an electronic component that generates heat by power supply. Examples of the heat generating component 22 include a reactor, a capacitor, a resistor, a relay, a transformer, a diode, and a semiconductor element. Examples of the semiconductor element include a field effect transistor (FET), a thyristor, a triac, and an insulated gate bipolar transistor (IGBT).

Volumes of at least some of the plurality of types of heat generating components 22 housed in the case 20 are different from each other. That is, the expression “plurality of types” means that at least one of the volumes of the heat generating components 22 or functions of the heat generating components 22 are different from each other. At least one of the plurality of types of heat generating components 22 housed in the case 20 is arranged in thermal contact with an inner wall surface of the case 20.

In the present embodiment, the heat generating components 22 being arranged in thermal contact with the inner wall surface means that the heat generating components 22 are arranged in thermal contact with the inner wall surface directly or via a heat transfer member or a heat transfer layer. The heat transfer member is a member having thermal conductivity, and the heat transfer layer is a layer having thermal conductivity.

Having thermal conductivity means having a property that causes a phenomenon in which thermal energy moves. Specifically, in the present embodiment, having thermal conductivity means having heat conductivity with which heat generated by the heat generating component 22 can be dissipated by transferring the heat to other members and the like.

In the present embodiment, a mode in which a first heat generating component 22A and a second heat generating component 22B are housed in the case 20 will be described as an example. The first heat generating component 22A and the second heat generating component 22B are different types of heat generating components 22, and have different volumes.

The first heat generating component 22A is a heat generating component 22 having a larger volume than the second heat generating component 22B.

The first heat generating component 22A is, for example, at least one of a reactor 22A1, a capacitor 22A2, a transformer 22A3, a resistor, and a relay. In the present embodiment, a mode in which the reactor 22A1, the capacitor 22A2, and the transformer 22A3 are housed in the case 20 as the first heat generating components 22A will be described as an example.

The second heat generating component 22B is a heat generating component 22 having a smaller volume than the first heat generating component 22A. The second heat generating component 22B is, for example, at least one semiconductor element of a diode, an FET, a thyristor, a triac, and an IGBT.

Specifically, the second heat generating component 22B is arranged in a gap formed by the first heat generating component 22A in the case 20. Specifically, the second heat generating component 22B is arranged in thermal contact with the inner wall surface of the case 20. Preferably, the second heat generating component 22B is arranged in contact with an insulating heat dissipation member 28 arranged in contact with the inner wall surface of the case 20 from the viewpoint of further ensuring an insulation property and a heat dissipation property of a surface of the second heat generating component 22B that faces the inner wall surface of the case 20. That is, at least one of the plurality of types of heat generating components 22 is preferably arranged in contact with the insulating heat dissipation member 28 arranged in contact with the inner wall surface of the case 20.

The insulating heat dissipation member 28 may be any member having the insulation property and the heat dissipation property. The insulating heat dissipation member 28 is, for example, a ceramic substrate. The insulating heat dissipation member 28 may be bonded and fixed to the inner wall surface of the case 20 with an adhesive or the like. The insulating heat dissipation member 28 may be fixed to the inner wall surface of the case 20 by filling the case 20 with the insulating heat dissipation resin material 24 in a state of being temporarily fixed to or temporarily held on the inner wall surface of the case 20 at the time of assembly.

The insulating heat dissipation resin material 24 is a resin material filled in the case 20, and has the insulation property and the heat dissipation property.

It is sufficient if the insulating heat dissipation resin material 24 is a resin having the insulation property and the heat dissipation property, and preferably, the insulating heat dissipation resin material 24 has curability. In the present embodiment, a mode in which the insulating heat dissipation resin material 24 has the insulation property, the heat dissipation property, and the curability will be described as an example. The insulating heat dissipation resin material 24 may be referred to as a potting resin material.

This will be described with reference to FIG. 4. FIG. 4 is a cross-sectional view of the power conversion device 2 illustrated in FIGS. 1 to 3 taken in a direction orthogonal to an arrangement direction of the reactor 22A1, the capacitor 22A2, and the transformer 22A3 mounted on the case 20.

The insulating heat dissipation resin material 24 is filled in the case 20. For example, the insulating heat dissipation resin material 24 is filled and cured in the case 20 after the first heat generating component 22A and the second heat generating component 22B are installed and housed in the case 20.

Therefore, the insulating heat dissipation resin material 24 is filled so as to completely cover a gap between the heat generating components 22 housed in the case 20. Therefore, a surface of each of the plurality of types of heat generating components 22 housed in the case 20 is covered with the insulating heat dissipation resin material 24.

Specifically, as described above, the second heat generating component 22B is at least one semiconductor element of a diode, an FET, a thyristor, a triac, and an IGBT. Therefore, a wire included in the second heat generating component 22B, which is a semiconductor element, is in direct contact with the insulating heat dissipation resin material 24 and is directly covered with the insulating heat dissipation resin material 24. Similarly, the surface of the first heat generating component 22A is covered with the insulating heat dissipation resin material 24.

In the power supply device 1 configured as described above, each of the plurality of types of heat generating components 22 generates heat by, for example, signal exchange between the circuit board 26 and each of the plurality of types of heat generating components 22 in the case 20. The heat generated from each of the plurality of types of heat generating components 22 reaches the heat dissipation housing 10 via the insulating heat dissipation resin material 24 and the case 20 that are in contact with the heat generating components 22, and is dissipated from the heat dissipation housing 10 to the outside.

Specifically, the heat generated from the first heat generating component 22A housed in the case 20 is transferred to the heat dissipation housing 10 via the insulating heat dissipation resin material 24 filled in the periphery and the case 20. This flow of heat transfer achieves heat dissipation of the first heat generating component 22A. The heat generated from the second heat generating component 22B arranged in thermal contact with the inner wall surface of the case 20 is transferred to the heat dissipation housing 10 via a contact region with the insulating heat dissipation resin material 24, the insulating heat dissipation resin material 24, and the case 20. The heat generated from the second heat generating component 22B is transferred to the heat dissipation housing 10 via the insulating heat dissipation member 28 and the case 20. This flow of heat transfer achieves heat dissipation of the second heat generating component 22B.

In the power supply device 1 according to the present embodiment, the plurality of types of heat generating components 22 are housed not outside the case 20 but inside the case 20, and the heat generating components 22 are not arranged on the outer wall of the case 20. In the power supply device 1 of the present embodiment, the insulating heat dissipation resin material 24 is filled in the case 20. Therefore, in the power supply device 1 of the present embodiment, it is not necessary to package the heat generating components 22 such as the semiconductor elements, and it is possible to significantly reduce the sizes of the power conversion device 2 and the power supply device 1.

As described above, the power supply device 1 of the present embodiment includes the case 20, the plurality of types of heat generating components 22, and the insulating heat dissipation resin material 24. The case 20 is a box-shaped member having thermal conductivity and formed in a box shape. The plurality of types of heat generating components 22 are housed in the case 20. The insulating heat dissipation resin material 24 is filled in the case 20.

Therefore, in the power supply device 1 of the present embodiment, the heat generated from each of the plurality of types of heat generating components 22 reaches the heat dissipation housing 10 via the insulating heat dissipation resin material 24 and the case 20 that are in contact with the heat generating components 22, and is dissipated by the heat dissipation housing 10. In the power supply device 1 of the present embodiment, the plurality of types of heat generating components 22 are housed in the case 20, and the heat generating components 22 are not arranged on the outer wall of the case 20. The surface of the heat generating component 22 is covered with the insulating heat dissipation resin material 24 filled in the case 20. Therefore, it is not necessary to package the heat generating components 22 such as the semiconductor elements, and it is possible to significantly reduce the sizes of the power conversion device 2 and the power supply device 1.

Therefore, the power supply device 1 of the present embodiment can ensure heat dissipation of the heat generating components 22 and can be reduced in size.

At least one of the plurality of types of heat generating components 22 is a semiconductor element, and a wire included in the semiconductor element is in direct contact with the insulating heat dissipation resin material 24. That is, the surface of the semiconductor element is protected by the insulating heat dissipation resin material 24, and heat dissipation by the insulating heat dissipation resin material 24 is achieved. Therefore, the insulating heat dissipation resin material 24 filled in the case 20 eliminates the need for resin molding (coating) of the surface of the semiconductor element with an insulating resin as in the related art, so that safety can be ensured and the power supply device 1 can be reduced in size.

With the power supply device of the present embodiment, it is possible to ensure heat dissipation of heat generating components and achieve size reduction of the entire device.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

The present technology can also have the following configurations.
(1) A power supply device includes: a case having thermal conductivity and formed in a box shape; a plurality of types of heat generating components housed in the case; and an insulating heat dissipation resin material filled in the case.
(2) In the power supply device according to (1), at least one of the plurality of types of heat generating components includes a semiconductor element, and a wire included in the semiconductor element is in direct contact with the insulating heat dissipation resin material.
(3) In the power supply device according to (1) or (2), at least one of the plurality of types of heat generating components is arranged in thermal contact with an inner wall surface of the case.
(4) In the power supply device according to any one of (1) to (3), volumes of at least some of the plurality of types of heat generating components are different from each other.
(5) In the power supply device according to any one of (1) to (4), the plurality of types of heat generating components include: a first heat generating component; and a second heat generating component having a smaller volume than the first heat generating component, the first heat generating component is arranged in the case, and the second heat generating component is arranged in a gap formed by the first heat generating component in the case.
(6) In the power supply device according to any one of (1) to (5), at least one of the plurality of types of heat generating components is arranged in contact with an insulating heat dissipation member arranged in contact with an inner wall surface of the case.
(7) In the power supply device according to any one of (1) to (6), the power supply device further includes a circuit board electrically connected to the heat generating components.
(8) In the power supply device according to any one of (1) to (7), the power supply device further includes a heat dissipation housing that houses the case, and the case is arranged in contact with an inner wall of the heat dissipation housing.
(9) In the power supply device according to any one of (5) to (8), the power supply device is used as a power supply conversion device, the first heat generating component includes at least one of a reactor, a capacitor, a resistor, a relay, and a transformer, and the second heat generating component includes at least one semiconductor element of a diode, a field effect transistor (FET), a thyristor, a triac, and an insulated gate bipolar transistor (IGBT).

What is claimed is:

1. A power supply device comprising:
a case having thermal conductivity and formed in a box shape;
a plurality of types of heat generating components housed in the case; and
an insulating heat dissipation resin material filled in the case.

2. The power supply device according to claim 1, wherein
at least one of the plurality of types of heat generating components includes a semiconductor element, and
a wire included in the semiconductor element is in direct contact with the insulating heat dissipation resin material.

3. The power supply device according to claim 1, wherein
at least one of the plurality of types of heat generating components is arranged in thermal contact with an inner wall surface of the case.

4. The power supply device according to claim 2, wherein
at least one of the plurality of types of heat generating components is arranged in thermal contact with an inner wall surface of the case.

5. The power supply device according to claim 1, wherein
volumes of at least some of the plurality of types of heat generating components are different from each other.

6. The power supply device according to claim 2, wherein
volumes of at least some of the plurality of types of heat generating components are different from each other.

7. The power supply device according to claim 3, wherein
volumes of at least some of the plurality of types of heat generating components are different from each other.

8. The power supply device according to claim 4, wherein
volumes of at least some of the plurality of types of heat generating components are different from each other.

9. The power supply device according to claim 1, wherein
the plurality of types of heat generating components include:
a first heat generating component; and
a second heat generating component having a smaller volume than the first heat generating component,
the first heat generating component is arranged in the case, and
the second heat generating component is arranged in a gap formed by the first heat generating component in the case.

10. The power supply device according to claim 1, wherein
at least one of the plurality of types of heat generating components is arranged in contact with an insulating heat dissipation member arranged in contact with an inner wall surface of the case.

11. The power supply device according to claim 1, further comprising a circuit board electrically connected to the heat generating components.

12. The power supply device according to claim 1, further comprising a heat dissipation housing that houses the case, wherein
the case is arranged in contact with an inner wall of the heat dissipation housing.

13. The power supply device according to claim 9, wherein
the power supply device is used as a power supply conversion device,
the first heat generating component includes at least one of a reactor, a capacitor, a resistor, a relay, and a transformer, and
the second heat generating component includes at least one semiconductor element of a diode, a field effect transistor (FET), a thyristor, a triac, and an insulated gate bipolar transistor (IGBT).

14. The power supply device according to claim 10, wherein
the power supply device is used as a power supply conversion device,
the first heat generating component includes at least one of a reactor, a capacitor, a resistor, a relay, and a transformer, and
the second heat generating component includes at least one semiconductor element of a diode, a field effect transistor (FET), a thyristor, a triac, and an insulated gate bipolar transistor (IGBT).

15. The power supply device according to claim 11, wherein
the power supply device is used as a power supply conversion device,
the first heat generating component includes at least one of a reactor, a capacitor, a resistor, a relay, and a transformer, and
the second heat generating component includes at least one semiconductor element of a diode, a field effect transistor (FET), a thyristor, a triac, and an insulated gate bipolar transistor (IGBT).

16. The power supply device according to claim 12, wherein
the power supply device is used as a power supply conversion device,
the first heat generating component includes at least one of a reactor, a capacitor, a resistor, a relay, and a transformer, and
the second heat generating component includes at least one semiconductor element of a diode, a field effect transistor (FET), a thyristor, a triac, and an insulated gate bipolar transistor (IGBT).
